(19) United States
(12) Patent Application Publication
(10) Pub. No.: US 2025/0224621 A1
(43) Pub. Date: Jul. 10, 2025

(54) POLARIZING PLATE AND STEREOSCOPIC IMAGE DISPLAY APPARATUS

(71) Applicant: SAMSUNG SDI CO., LTD., Yongin-si (KR)

(72) Inventors: Dae Hee KWAK, Suwon-si (KR); Jun Mo KOO, Suwon-si (KR); Bong Choon KIM, Suwon-si (KR); Hye Yeon JWA, Suwon-si (KR); Mun Bo KO, Suwon-si (KR); Kwang Ho SHIN, Suwon-si (KR)

(21) Appl. No.: 19/009,820

(22) Filed: Jan. 3, 2025

(30) Foreign Application Priority Data
Jan. 8, 2024 (KR) 10-2024-0002827

(51) Int. Cl. G02B 30/26; G02B 27/28

(52) U.S. Cl. CPC G02B 30/26; G02B 27/28

(57) ABSTRACT

A polarizing plate and a stereoscopic image display apparatus including the same are disclosed. A polarizing plate includes: a polarizer; and a stack of a first negative wavelength dispersion retardation layer and a positive C retardation layer on at least one surface of the polarizer, and the stack has a degree of biaxiality of 0.1 to 0.5 at a wavelength of 450 nm, a degree of biaxiality of 0.2 to 0.6 at a wavelength of 550 nm, and a degree of biaxiality of 0.3 to 0.7 at a wavelength of 650 nm.

### CROSS-REFERENCE TO RELATED APPLICATION

The present application claims priority to and the benefit of Korean Patent Application No. 10-2024-0002827, filed on Jan. 8, 2024 in the Korean Intellectual Property Office, the entire disclosure of which is incorporated herein by reference.

### BACKGROUND

### 1. Field

Aspects of embodiments of the present invention relate to a polarizing plate and a stereoscopic image display apparatus.

### 2. Description of the Related Art

Recently, display apparatuses that can display stereoscopic images rather than simply displaying images on a flat screen have been attracting attention.

Conventional stereoscopic image display apparatuses use pancake lenses. However, a stereoscopic image provided by such an apparatus has limited resolution. Here, resolution refers to contrast ratio, that is, a difference in brightness between light and dark areas on a screen of the display apparatus. It may be desirable that such a stereoscopic image display apparatus provide a wide lateral field of view.

The background technique of the present invention is disclosed in Korean Patent Laid-open Publication No. 10-2013-0103595 and the like.

### SUMMARY

According to an aspect of one or more embodiments of the present invention, a polarizing plate for stereoscopic image display apparatuses that can produce a same level of light output for each wavelength to allow a user to perceive the same level of light output for each wavelength, can eliminate light leakage at an edge of a screen within a viewer's field of view, and can provide high resolution and a wide field of view, and a stereoscopic image display apparatus including the same, are provided.

According to one or more embodiments of the present invention, a polarizing plate includes: a polarizer; and a retardation layer stack of a first negative wavelength dispersion retardation layer and a positive C retardation layer laminated on at least one surface of the polarizer, wherein the retardation layer stack has a degree of biaxiality of 0.1 to 0.5 at a wavelength of 450 nm, a degree of biaxiality of 0.2 to 0.6 at a wavelength of 550 nm, and a degree of biaxiality of 0.3 to 0.7 at a wavelength of 650 nm.

According to one or more embodiments of the present invention, a stereoscopic image display apparatus includes: a display unit including a light emitting device; a first polarizing plate; and a pancake lens assembly, wherein the first polarizing plate includes the polarizing plate according to an embodiment of the present invention.

Embodiments of the present invention provide a polarizing plate for stereoscopic image display apparatuses that can produce a same level of light output for each wavelength to allow a user to perceive the same level of light output for each wavelength, can eliminate light leakage at an edge of a screen within a viewer's field of view, and can provide high resolution and a wide field of view, and a stereoscopic image display apparatus including the same.

### BRIEF DESCRIPTION OF THE DRAWINGS

FIG. 1 is a diagram illustrating a relationship between optical axes of a polarizing plate according to an embodiment.

FIG. 2 is a cross-sectional view of a polarizing plate according to an embodiment.

FIG. 3 is a cross-sectional view of a polarizing plate according to another embodiment.

FIG. 4 is a cross-sectional view of a polarizing plate according to another embodiment.

FIG. 5 is a schematic diagram of a stereoscopic image display apparatus according to an embodiment.

FIG. 6 is a diagram illustrating an axial relationship between a first polarizing plate and a retardation film of a pancake lens assembly, according to an embodiment.

FIG. 7 is a schematic diagram of a stereoscopic image display apparatus according to another embodiment.

FIG. 8 is a diagram illustrating an axial relationship between a first polarizing plate, a retardation film of a pancake lens assembly, and a third polarizer of the pancake lens assembly, according to another embodiment.

FIG. 9 is a cross-sectional view of a second polarizing plate according to an embodiment.

FIG. 10 is a schematic diagram of a stereoscopic image display apparatus according to another embodiment.

FIG. 11 is a diagram illustrating an axial relationship between a first polarizing plate, a second polarizing plate, and a retardation film of a pancake lens assembly according to an embodiment.

### DETAILED DESCRIPTION

Some example embodiments of the present invention will be described in further detail with reference to the accompanying drawings to facilitate practice by one of ordinary skill in the art to which the present invention pertains. It is to be understood that the present invention may be embodied in different ways and is not limited to the following embodiments. In the drawings, portions irrelevant to the description may be omitted for clarity. Like components will be denoted by like reference numerals throughout the specification. Lengths, sizes, and the like of components in the drawings are for the purpose of illustrating the invention, but the invention is not limited thereto.

The terminology used herein is for the purpose of describing some example embodiments and is not intended to limit the present invention. As used herein, the singular forms, “a,” “an,” and “the” are intended to include the plural forms as well, unless the context clearly indicates otherwise.

Herein, spatially relative terms such as “upper” and “lower” are defined with reference to the accompanying drawings. Thus, it is to be understood that the term “upper surface” can be used interchangeably with the term “lower surface,” and when an element, such as a layer or film, is referred to as being placed “on” another element, it may be directly placed on the other element, or intervening element(s) may be present. On the other hand, when an element is referred to as being placed “directly on” another element, there are no intervening element(s) therebetween.

Herein, “in-plane retardation Re”, “out-of-plane retardation Rth”, and “degree of biaxiality NZ” are represented by the following Equations A, B, and C, respectively:

$$Re = ( nx - ny ) \times d , \qquad ( A ) ;$$

$$Rth = ( ( nx + ny ) / 2 - nz ) \times d , \qquad ( B ) ;$$

$$NZ = ( nx - nz ) / nx - ny ) , \qquad ( C ) ,$$

where nx, ny, and nz are the indexes of refraction of a corresponding optical element, as measured in the slow axis direction, the fast axis direction, and the thickness direction thereof at a measurement wavelength, respectively, and d is the thickness thereof (unit: nm).

Herein, “slow axis” refers to an axis in which the index of refraction of the optical element in the in-plane direction attains a maximum level, and “fast axis” refers to an axis in which the index of refraction of the optical element in the in-plane direction attains a minimum level.

In Equations A to C, the “optical element” may be a retardation layer, a protective layer, or a retardation layer stack. In Equations A to C, the “measurement wavelength” may be 450 nm, 550 nm, or 650 nm.

Herein, “short wavelength dispersion” refers to Re(450)/Re(550), and “long wavelength dispersion” refers to Re(650)/Re(550), wherein Re(450), Re(550), and Re(650) refer to in-plane retardation (Re) of a retardation layer at wavelengths of about 450 nm, 550 nm, and 650 nm, respectively.

Herein, “negative wavelength dispersion” means short wavelength dispersion <1 and long wavelength dispersion >1.

Herein, “positive C retardation layer” means that the corresponding layer has a refractive index relationship where nz>nx≈ny.

Herein, “crossed transmittance (Tc)” is an average of values measured on polarized light passing through polarizers arranged orthogonal to each other at a wavelength of 380 nm to 780 nm.

As used herein to represent a specific numerical range, the expression “X to Y” means “greater than or equal to X and less than or equal to Y (X≤ and ≤Y)”.

Disclosed herein is a polarizing plate for stereoscopic image display apparatuses that can produce the same level of light output for each wavelength to allow a user to perceive the same level of light output for each wavelength, can eliminate light leakage at an edge of a screen within a viewer's field of view, and can provide high resolution. In particular, when used as a polarizing plate for stereoscopic image display apparatuses including a pancake lens assembly, the polarizing plate according to the present invention can enhance contrast ratio and resolution and can eliminate light leakage occurring at an edge of a screen within a viewer's field of view.

Further, the polarizing plate of the present invention can provide a wide field of view (FOV) when used in stereoscopic image display apparatuses. Use of a negative wavelength dispersion retardation film to provide a wide field of view can cause light leakage and ghost images at lateral sides of a screen due to decrease in ellipticity at the lateral sides of the screen. The polarizing plate of the present invention can avoid these problems, thereby widening a field of view within which light leakage and ghost images do not occur.

In accordance with an aspect of one or more embodiments of the present invention, a polarizing plate includes: a polarizer; and a retardation layer stack of a first negative wavelength dispersion retardation layer and a positive C retardation layer laminated on at least one surface of the polarizer, wherein the retardation layer stack has a degree of biaxiality of 0.1 to 0.5 at a wavelength of 450 nm, a degree of biaxiality of 0.2 to 0.6 at a wavelength of 550 nm, and a degree of biaxiality of 0.3 to 0.7 at a wavelength of 650 nm.

In one or more embodiments, the retardation layer stack may have different degrees of biaxiality at wavelengths 450 nm, 550 nm, and 650 nm, respectively.

### Stack of First Negative Wavelength Dispersion Retardation Layer and Positive C Retardation Layer

If the degree of biaxiality of the retardation layer stack at a wavelength of 450 nm is less than 0.1 or exceeds 0.5, blue ghost images can be perceived due to leakage of short-wavelength light at an edge of a screen within a viewer's field of view. For example, the retardation layer stack may have a degree of biaxiality of 0.1 to 0.4 or 0.2 to 0.4 at a wavelength of 450 nm. Within this range, the retardation layer stack can be more effective at providing the desired effects of the present invention.

If the degree of biaxiality of the retardation layer stack at a wavelength of 550 nm is less than 0.2 or exceeds 0.6, green ghost images can be perceived due to leakage of mid-wavelength light at an edge of a screen within a viewer's field of view. For example, the retardation layer stack may have a degree of biaxiality of 0.2 to 0.5 or 0.3 to 0.5 at a wavelength of 550 nm. Within this range, the retardation layer stack can be more effective at providing the desired effects of the present invention.

If the degree of biaxiality of the retardation layer stack at a wavelength of 650 nm is less than 0.3 or exceeds 0.7, red ghost images can be perceived due to leakage of long-wavelength light at an edge of a screen within a viewer's field of view. For example, the retardation layer stack may have a degree of biaxiality of 0.3 to 0.6 or 0.3 to 0.5 at a wavelength of 650 nm. Within this range, the retardation layer stack can be more effective at providing the desired effects of the present invention.

According to an embodiment, the degrees of biaxiality of the retardation layer stack at wavelengths of 450 nm, 550 nm, and 650 nm may be adjusted to the ranges described above by adjusting the in-plane retardation and out-of-plane retardation of the retardation layer stack. The in-plane retardation and out-of-plane retardation of the retardation layer stack may be adjusted by adjusting the in-plane retardation and/or out-of-plane retardation of the first negative wavelength dispersion retardation and/or the positive C retardation layer of the retardation layer stack.

The retardation layer stack has negative wavelength dispersion and, in an embodiment, may have an in-plane retardation of 112 nm to 132 nm, for example, 117 nm to 127 nm, at a wavelength of 450 nm, an in-plane retardation of 130 nm to 150 nm, for example, 136 nm to 146 nm, at a wavelength of 550 nm, and an in-plane retardation of 133 nm to 153 nm, for example, 138 nm to 148 nm, at a wavelength of 650 nm. Within these ranges, the retardation layer stack can have a degree of biaxiality within the range described above.

In an embodiment, the retardation layer stack may have an out-of-plane retardation of −70 nm to −10 nm, for example, −60 nm to −30 nm, at a wavelength of 450 nm, an out-of-plane retardation of −55 nm to 5 nm, for example, −45 nm to −10 nm, at a wavelength of 550 nm, and an out-of-plane retardation of −40 nm to 15 nm, for example, −25 nm to 5 nm, at a wavelength of 650 nm. Within these ranges, the retardation layer stack can have a degree of biaxiality within the range described above.

According to another embodiment, the degrees of biaxiality of the retardation layer stack at wavelengths 450 nm, 550 nm, and 650 nm may be adjusted to the ranges described above by adjusting the in-plane retardation and/or out-of-plane retardation and/or degree of biaxiality of the first negative dispersion retardation layer and/or the positive C layer of the retardation layer stack.

In an embodiment, the first negative wavelength dispersion retardation layer may have an in-plane retardation of 115 nm to 125 nm, for example, 119 nm to 123 nm, at a wavelength of 450 nm, an in-plane retardation of 135 nm to 145 nm, for example, 139 nm to 143 nm, at a wavelength of 550 nm, and an in-plane retardation of 140 nm to 150 nm, for example, 142 nm to 146 nm, at a wavelength of 650 nm. Within these ranges, the retardation layer stack can have a degree of biaxiality within the ranges described above.

In an embodiment, the first negative wavelength dispersion retardation layer may have an out-of-plane retardation of 40 nm to 60 nm, for example, 50 nm to 60 nm, at a wavelength of 450 nm, an out-of-plane retardation of 50 nm to 70 nm, for example, 55 nm to 70 nm, at a wavelength of 550 nm, and an out-of-plane retardation of 60 nm to 75 nm, for example, 65 nm to 75 nm, at a wavelength of 650 nm. Within these ranges, the retardation layer stack can have a degree of biaxiality within the ranges described above.

In an embodiment, the first negative wavelength dispersion retardation layer may have a degree of biaxiality of 0.82 to 1.02, for example, 0.91 to 1.00, at a wavelength of 450 nm, a degree of biaxiality of 0.84 to 1.02, for example, 0.88 to 1.00, at a wavelength of 550 nm, and a degree of biaxiality of 0.90 to 1.04, for example, 0.95 to 1.03, at a wavelength of 650 nm. Within these ranges, the retardation layer stack can have a degree of biaxiality within the ranges described above.

In an embodiment, the positive C retardation layer may have an in-plane retardation of −3 nm to 7 nm, for example, −2 nm to 4 nm, at a wavelength of 450 nm, an in-plane retardation of −5 nm to 5 nm, for example, −3 nm to 3 nm, at a wavelength of 550 nm, and an in-plane retardation of −7 nm to 3 nm, for example, −4 nm to 2 nm, at a wavelength of 650 nm. Within these ranges, the retardation layer stack can have a degree of biaxiality within the ranges described above.

The positive C retardation layer has a negative out-of-plane retardation at wavelengths of 450 nm, 550 nm, and 650 nm, and, in an embodiment, may have an out-of-plane retardation of −120 nm to −70 nm, for example, −110 nm to −70 nm, at a wavelength of 450 nm, an out-of-plane retardation of −105 nm to −65 nm, for example, −100 nm to −70 nm, at a wavelength of 550 nm, and an out-of-plane retardation of −100 nm to −60 nm, for example, −95 nm to −65 nm or −95 nm to −70 nm, at a wavelength of 650 nm. Within these ranges, the retardation layer stack can have a degree of biaxiality within the ranges described above.

In an embodiment, the positive C retardation layer may have positive wavelength dispersion, and the positive C retardation layer can thereby be effective at providing the desired effects of the present invention. Herein, “positive wavelength dispersion” means that the positive C retardation layer satisfies the following Equation 1:

$$\vert {R}_{th} ( 450 ) \vert > \vert {R}_{th} ( 550 ) \vert > \vert {R}_{th} ( 650 ) \vert , \qquad ( 1 ) ,$$

where Rₜₕ(450), Rₜₕ(550), and Rₜₕ(650) are out-of-plane retardations of the positive C retardation layer, as measured at wavelengths 450 nm, 550 nm, and 650 nm, respectively.

For example, a ratio of |Rₜₕ(450)| to |Rₜₕ (550)| (|Rₜₕ (450)|/|Rₜₕ (550)|) may be in a range from 1.01 to 1.14, for example, 1.01 to 1.09, and a ratio of |Rₜₕ (650)| to |Rₜₕ (550)| (|Rₜₕ (650)|/|Rₜₕ (550)|) may be in a range from 0.92 to 0.99, for example, 0.94 to 0.99. Within these ranges, the positive C retardation layer can be effective at providing the desired effects of the present invention.

In an embodiment, the first negative wavelength dispersion retardation layer may have a short wavelength dispersion of 0.81 to 0.88 and a long wavelength dispersion of 1.01 to 1.10. Within these ranges, the polarizing plate can be effective at eliminating or reducing light leakage and providing high resolution when used in a stereoscopic image display apparatus. For example, the first negative wavelength dispersion retardation layer may have a short wavelength dispersion of 0.81 to 0.86 or 0.81 to 0.84 and a long wavelength dispersion of 1.01 to 1.07 or 1.01 to 1.04.

In an embodiment, the first negative wavelength dispersion retardation layer may have a thickness of 1 μm to 40 μm, for example, 1.5 μm to 35 μm. Within this range, the first negative wavelength dispersion retardation layer can be used in the polarizing plate.

According to an embodiment, the first negative wavelength dispersion retardation layer may include a liquid crystal layer or a non-liquid crystal layer. The liquid crystal layer and the non-liquid crystal layer may be formed of any suitable material that can satisfy the wavelength dispersion and retardation requirements of the first negative wavelength dispersion retardation layer.

In some embodiments, the first negative wavelength dispersion retardation layer may be a liquid crystal layer or a non-liquid crystal layer.

In an embodiment, the first negative wavelength dispersion retardation layer may include a liquid crystal layer. For example, the liquid crystal layer may include a cured product of a liquid crystal composition including at least one of a nematic liquid crystal, a smectic liquid crystal, a discotic liquid crystal, or a cholesteric liquid crystal. In an embodiment, the first negative wavelength dispersion retardation layer may further include an alignment film to facilitate alignment of a liquid crystal in the liquid crystal layer. Here, the liquid crystal layer and the alignment film can be easily manufactured by a typical method known to those skilled in the art.

The first negative wavelength dispersion retardation layer may further include an optical film.

The optical film can facilitate formation of the first negative wavelength dispersion retardation layer without affecting the retardation characteristics of the first negative wavelength dispersion retardation layer. In an embodiment, the optical film may have an in-plane retardation of 10 nm or less, for example, 0 nm to 5 nm, at a wavelength of 550 nm. Within this range, the optical film can have no influence on the retardation characteristics of the first negative wavelength dispersion retardation layer.

In an embodiment, the optical film may be a film including an optically transparent resin. For example, the resin may include at least one of a cellulose resin, such as triacetyl cellulose, a polyester resin, such as polyethylene terephthalate (PET), polybutylene terephthalate, polyethylene naphthalate, and polybutylene naphthalate, a cyclic olefin copolymer (COC) resin, a cyclic olefin polymer (COP) resin, a polycarbonate resin, a polyether sulfone resin, a polysulfone resin, a polyamide resin, a polyimide resin, a polyolefin resin, a polyarylate resin, a polyvinyl alcohol resin, a polyvinyl chloride resin, a polyvinylidene chloride resin, or an acrylic resin.

In another embodiment, the first negative wavelength dispersion retardation layer may include a non-liquid crystal layer.

For example, the non-liquid crystal layer may be a film obtained by uniaxially stretching an unstretched film in the MD (machine direction) or TD (transverse direction) thereof or by biaxially stretching the unstretched film in the MD and TD thereof. For example, the non-liquid crystal layer may be a coating layer.

In an embodiment, the unstretched film may include an optically transparent resin as described above.

For example, the non-liquid crystal layer may be a coating layer obtained by coating a composition including at least one of a cellulose based compound or a polystyrene based compound as a main component, followed by drying and/or curing of the composition.

In an embodiment, the first negative wavelength dispersion retardation layer may further include an optical film.

The optical film can facilitate formation of the coating layer without affecting the retardation characteristics of the first negative wavelength dispersion retardation layer. The optical film may be substantially the same as that described above, and further detailed description thereof will be omitted.

The positive C retardation layer may be formed of any suitable material that can satisfy the wavelength dispersion and retardation requirements of the positive C retardation layer. The positive C retardation layer may include a liquid crystal layer or a non-liquid crystal layer. The liquid crystal layer and the non-liquid crystal layer may be the same as those described above.

According to an embodiment, in the polarizing plate, the first negative wavelength dispersion retardation layer may be disposed between the polarizer and the positive C retardation layer. With this structure, the polarizing plate can provide a wide field of view as described above while enhancing resolution.

According to an embodiment, the first negative wavelength dispersion retardation layer may be directly formed on the positive C retardation layer.

According to another embodiment, an adhesive layer, a bonding layer, or an adhesive bonding layer may be further formed between the first negative wavelength dispersion retardation layer and the positive C retardation layer.

In an embodiment, the polarizing plate may further include a second negative wavelength dispersion retardation layer.

### Second Negative Wavelength Dispersion Retardation Layer

The second negative wavelength dispersion retardation layer can ensure that the polarizing plate is effective at eliminating light leakage and enhancing resolution when used in a stereoscopic image display apparatus.

In an embodiment, the second negative wavelength dispersion retardation layer may have a short wavelength dispersion of 0.81 to 0.88, for example, 0.81 to 0.86 or 0.81 to 0.84. In an embodiment, the second negative wavelength dispersion retardation layer may have a long wavelength dispersion of 1.01 to 1.10, for example, 1.01 to 1.08 or 1.01 to 1.04. Within these ranges, the second negative wavelength dispersion retardation layer can aid in eliminating or reducing light leakage and enhancing resolution in conjunction with the first negative wavelength dispersion retardation layer having the aforementioned wavelength dispersion characteristics.

In an embodiment, the short wavelength dispersion of the second negative wavelength dispersion retardation layer may have substantially the same value as that of the first negative wavelength dispersion retardation layer, and the long wavelength dispersion of the second negative wavelength dispersion retardation layer may have substantially the same value as that of the first negative wavelength dispersion retardation layer. Accordingly, the second negative wavelength dispersion retardation layer can facilitate achievement of the desired effects of the present invention. In particular, if the second negative wavelength dispersion retardation layer is disposed on both surfaces of the polarizer, and the positive C retardation layer having the aforementioned wavelength dispersion characteristics is disposed on one surface of the polarizer, the polarizing plate can be effective at providing the desired effects of the present invention.

In an embodiment, the second negative wavelength dispersion retardation layer may have an in-plane retardation of 115 nm to 125 nm, for example, 119 nm to 123 nm, at a wavelength of 450 nm, an in-plane retardation of 135 nm to 145 nm, for example, 139 nm to 143 nm, at a wavelength of 550 nm, and an in-plane retardation of 140 nm to 150 nm, for example, 142 nm to 146 nm, at a wavelength of 650 nm. Within these ranges, the second negative wavelength dispersion retardation layer can have a short wavelength dispersion and a long wavelength dispersion falling within the ranges described above.

In an embodiment, the second negative wavelength dispersion retardation layer may have an out-of-plane retardation of 50 nm to 80 nm, for example, 55 nm to 75 nm, at a wavelength of 550 nm. Within this range, the second negative wavelength dispersion retardation layer can have an in-plane retardation within the range described above while allowing reduction in thickness of the polarizing plate.

In an embodiment, the second negative wavelength dispersion retardation layer may have a degree of biaxiality of 0.7 to 1.1, for example, 0.8 to 1.0, at a wavelength of 550 nm. Within this range, the second negative wavelength dispersion retardation layer can have an in-plane retardation within the range described above while allowing reduction in thickness of the polarizing plate.

In an embodiment, the second negative wavelength dispersion retardation layer may have a thickness of 1 μm to 40 μm, for example, 1.5 μm to 35 μm. Within this range, the second negative wavelength dispersion retardation layer can be used in the polarizing plate.

The second negative wavelength dispersion retardation layer may be formed of any suitable material that can satisfy the wavelength dispersion and retardation requirements of the second negative wavelength dispersion retardation layer. The second negative wavelength dispersion retardation layer may include a liquid crystal layer or a non-liquid crystal layer. The liquid crystal layer and the non-liquid crystal layer may be substantially the same as those described above. The second negative wavelength dispersion retardation layer may further include an optical film as described above. The second negative wavelength dispersion retardation layer may be a liquid crystal layer or a non-liquid crystal layer.

According to an embodiment, the polarizing plate may have a structure in which the first negative wavelength dispersion retardation layer is disposed on a surface of the polarizer and the second negative wavelength dispersion retardation layer is disposed on another surface of the polarizer. With this structure, the polarizing plate can provide elimination or reduction of light leakage and enhancement in resolution.

In the polarizing plate, an axial relationship (e.g., a predetermined axial relationship) may exist between the polarizer, the first negative wavelength dispersion retardation layer, and the second negative wavelength dispersion retardation layer. According to an embodiment, a slow axis of the first negative wavelength dispersion retardation layer may be orthogonal to a slow axis of the second negative wavelength dispersion retardation layer. Accordingly, the polarizing plate can be effective at providing the desired effects of the present invention.

For example, the slow axis of the first negative wavelength dispersion retardation layer may be tilted at an angle of approximately 45° with respect to a light absorption axis of the polarizer, and the slow axis of the second negative wavelength dispersion retardation layer may be tilted at an angle of approximately 135° with respect to the light absorption axis of the polarizer.

In an embodiment, the slow axis of the first negative wavelength dispersion retardation layer may be tilted at an angle of approximately 135° with respect to the light absorption axis of the polarizer, and the slow axis of the second negative wavelength dispersion retardation layer may be tilted at an angle of approximately 45° with respect to the light absorption axis of the polarizer.

### Polarizer

The polarizer linearly polarizes circularly polarized light coming in from the first negative wavelength dispersion retardation layer or the second negative wavelength dispersion retardation layer and allows the linearly polarized light to exit the polarizer.

In an embodiment, the polarizer may have a crossed transmittance of 0.2% or less, for example, 0% to 0.2%. Within this range, the polarizer can aid in minimizing or reducing ghost images by enhancing antireflection performance of a display apparatus in which an angular relationship between the slow axes is set as described above.

In an embodiment, the polarizer may have a degree of polarization of 99% or more, for example, 99.99% to 100%, and a single light transmittance (Ts) of 42% or more, for example, 42% to 45%. Within these ranges of degree of polarization and single light transmittance, the polarizer can have significantly low reflectance when used in the polarizing plate. Here, the “single light transmittance” refers to a single light transmittance (Ts) measured in the visible spectrum, for example, at a wavelength of 400 nm to 700 nm, and may be measured by a typical method known to those skilled in the art. In addition, the “degree of polarization” may be measured by a typical method known to those skilled in the art. In an embodiment, the polarizer may have a degree of polarization of 99% to 99.9999% and a single light transmittance of 42% to 50%.

The light absorption axis of the polarizer may correspond to a stretching direction of a polyvinyl alcohol film in manufacture of the polarizer therefrom, for example, the machine direction (MD) of the polarizer. The polarizer may include a polyvinyl alcohol-based polarizer obtained by uniaxially stretching a polyvinyl alcohol film. In an embodiment, the polarizer may be manufactured by subjecting the polyvinyl alcohol film to dyeing, stretching, crosslinking, and color correction processes. A polarizer having a degree of polarization and light transmittance within the ranges described above may be obtained by appropriately varying conditions of the dyeing, stretching, crosslinking, and color correction processes described above.

In an embodiment, the polarizer may have a thickness of 5 μm to 40 μm. Within this range, the polarizer can be used in the polarizing plate.

The polarizing plate may further include a resin layer formed on at least one surface of the polarizer.

### Resin Layer

In an embodiment, the resin layer may be directly formed on at least one surface of the polarizer. Herein, the expression “directly formed” means that no other adhesive layer, bonding layer, and/or curable coating layer is formed between the polarizer and the resin layer. The resin layer can improve the effectiveness of the polarizing plate in elimination or reduction of ghost images by covering fine surface irregularities of the polarizer. The resin layer may be a cured product of a composition including at least one of a heat-curable resin or a UV-curable resin. Each of the heat-curable resin and the UV-curable resin may be selected from among typical heat-curable resins or UV-curable resins known to those skilled in the art. For example, the resin layer may be a cured product of a composition including a (meth)acrylic resin. In an embodiment, the resin layer may be a hard coating layer, without being limited thereto.

The polarizing plate may further include a stack of a resin layer and an optical film on at least one surface of the polarizer.

### Stack of Resin Layer and Optical Film

The optical film can increase mechanical strength of the polarizer, and the resin layer can improve effectiveness of the polarizing plate in elimination of ghost images by covering fine surface irregularities of the optical film.

The resin layer and the optical film may be substantially the same as those described above.

In an embodiment, the optical film and the resin layer may be sequentially stacked on the polarizer.

The polarizing plate may further include a protective layer.

### Protective Layer

The protective layer may be formed on one or both surfaces of the polarizer.

The protective layer can protect the polarizer and can improve reliability and mechanical strength of the polarizing plate. The protective layer may be omitted if desired mechanical properties of the polarizing plate can be secured without the protective layer.

The protective layer may include at least one of an optically transparent protective film or an optically transparent protective coating layer.

The protective film may include a film formed of at least one of a cellulose ester resin, such as triacetylcellulose (TAC), a cyclic polyolefin resin, such as amorphous cyclic polyolefin (COP), a polycarbonate resin, a polyester resin, such as polyethylene terephthalate (PET), a polyether sulfone resin, a polysulfone resin, a polyamide resin, a polyimide resin, an acyclic polyolefin resin, a poly(meth)acrylate resin, such as poly(methyl methacrylate), a polyvinyl alcohol resin, a polyvinyl chloride resin, or a polyvinylidene chloride resin, without being limited thereto.

The protective coating layer may be formed of an actinic radiation-curable resin composition including an actinic radiation-curable compound and a polymerization initiator. The actinic radiation-curable compound may include at least one of a cationic polymerizable curable compound, a radical polymerizable curable compound, a urethane resin, or a silicone resin.

The protective layer may be a zero retardation layer or may have an in-plane retardation in a certain range (e.g., a predetermined range). For example, the protective layer may have an in-plane retardation of less than 5,000 nm, greater than or equal to 5,000 nm, 120 nm to 160 nm, or 5 nm to 0 nm, at a wavelength of 550 nm. Within this range, the protective layer can protect the polarizing plate without altering the desired effects of the retardation layer stack.

In an embodiment, the protective layer may have a thickness of 10 μm or less, 5 μm to 300 μm, 5 μm or less, or 5 μm to 200 μm. Within this range, the protective layer can be used in the polarizing plate.

The polarizing plate may further include a functional coating layer formed on one or both sides of the protective layer.

The functional coating layer can provide additional functionality to the protective layer or the polarizing plate. The functional coating layer may include at least one of a hard coating layer, an anti-fingerprint layer, an antireflection layer, an antiglare layer, a low reflectivity layer, or an ultra-low reflectivity layer, without being limited thereto.

In an embodiment, the functional coating layer may be a low reflectivity layer, an antireflection layer, or an antiglare layer. The low reflectivity layer, the antireflection layer, or the antiglare layer can aid in minimizing or reducing ghost images by reflecting unwanted light coming from the outside or by absorbing light reflected at an interface. The polarizing plate may include at least one of the low reflectivity layer, the antireflection layer, or the antiglare layer.

For example, each of the low reflectivity layer and the antireflection layer may have a minimum reflectance of 3% or less, for example, 0% to 2%. Within this range, the low reflectivity layer and the antireflection layer can aid in minimizing or reducing ghost images.

For example, the antiglare layer may have an external haze of 0% to 50% and an internal haze of 0% to 10%. Within these ranges, the antiglare layer can aid in minimizing or reducing ghost images. Herein, “internal haze” is a value measured in the same manner as in measurement of overall haze of the polarizing plate after spraying alcohol (for example, ethanol) on a glass plate having an overall haze of less than 1%, followed by attaching the glass plate to the antiglare layer to flatten surface irregularities of the antiglare layer. Herein, “overall haze” of the antiglare layer is a value measured using a typical haze meter, for example, a haze meter NHD-2000. Herein, “external haze” of the antiglare layer may be a difference between the overall haze of the antiglare layer and the internal haze of the antiglare layer. Herein, “haze” is measured in the visible spectrum, for example, at a wavelength of 380 nm to 780 nm, and refers to an average value, unless otherwise stated.

The low reflectivity layer, the antireflection layer, and the antiglare layer may be manufactured by a typical method known to those skilled in the art.

FIG. 1 is a diagram illustrating a relationship between optical axes of a polarizing plate according to an embodiment.

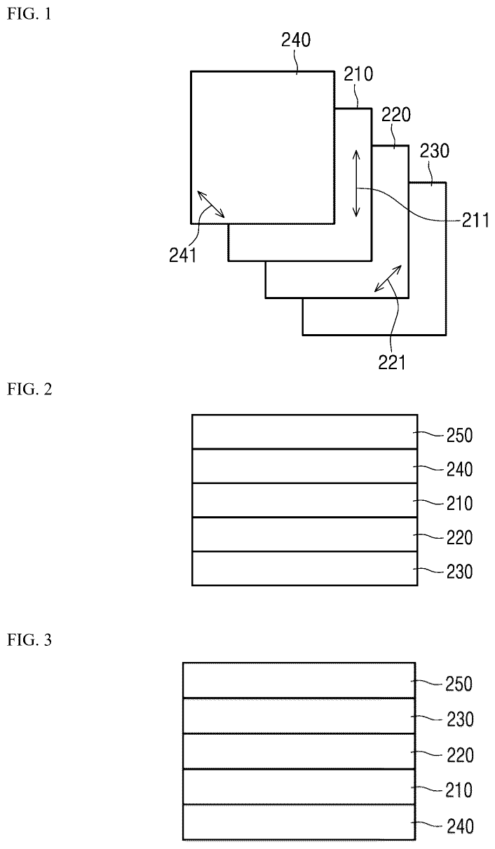

Referring to FIG. 1, the polarizing plate may include: a first negative wavelength dispersion retardation layer 220 and a positive C retardation layer 230 sequentially stacked on a surface of a polarizer 210; and a second negative wavelength dispersion retardation layer 240 and, in an embodiment, a protective layer 250, as further shown in FIG. 2, sequentially stacked on another surface of the polarizer.

A slow axis 221 of the first negative wavelength dispersion retardation layer 220 may be substantially orthogonal to a slow axis 241 of the second negative wavelength dispersion retardation layer 240 and may be tilted at an angle of substantially 45° or 135° with respect to a light absorption axis 211 of the polarizer 210.

### Structure of Polarizing Plate

The retardation layer stack may be formed on at least one surface of the polarizer.

According to an embodiment, the retardation layer stack may be formed on only one surface of the polarizer. Here, the second negative wavelength dispersion retardation layer may be formed on another surface of the polarizer.

According to another embodiment, the retardation layer stack may be formed on both, or opposite, surfaces of the polarizer.

FIG. 2 to FIG. 4 illustrate polarizing plates according to some embodiments.

Referring to FIG. 2, the polarizing plate may include: the polarizer 210; the first negative wavelength dispersion retardation layer 220 and the positive C retardation layer 230 sequentially stacked on a surface of the polarizer 210; and the second negative wavelength dispersion retardation layer 240 and the protective layer 250 sequentially stacked on another surface of the polarizer 210. Although not shown in FIG. 2, the polarizing plate may further include a functional coating layer as described above on the another surface of the protective layer. Although not shown in FIG. 2, the polarizing plate may further include a resin layer, an optical film, or a stack thereof as described above between the polarizer 210 and the second negative wavelength dispersion retardation layer 240.

Referring to FIG. 3, the polarizing plate may include: the polarizer 210; the second negative wavelength dispersion retardation layer 240 stacked on a surface of the polarizer 210; and the first negative wavelength dispersion retardation layer 220, the positive C retardation layer 230, and the protective layer 250 sequentially stacked on another surface of the polarizer 210. Although not shown in FIG. 3, the polarizing plate may further include a functional coating layer as described above on the another surface of the protective layer. Although not shown in FIG. 3, the polarizing plate may further include a resin layer, an optical film, or a stack thereof as described above on one or both surfaces of the polarizer 210.

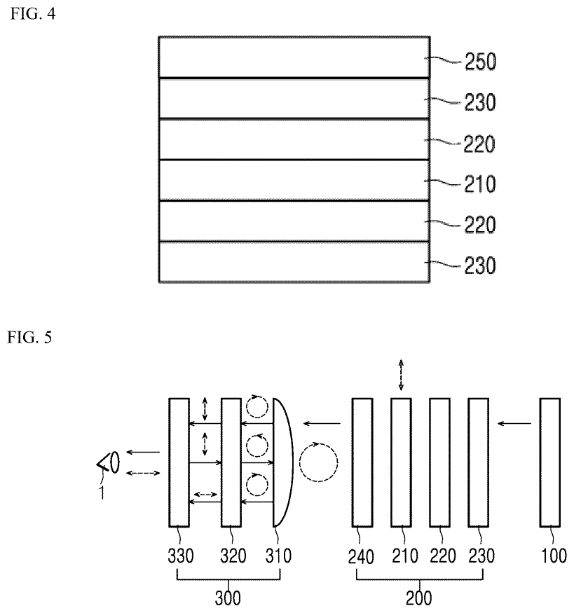

Referring to FIG. 4, the polarizing plate may include: the polarizer 210; the first negative wavelength dispersion retardation layer 220 and the positive C retardation layer 230 sequentially stacked on a surface of the polarizer 210; and a first negative wavelength dispersion retardation layer 220, a positive C retardation layer 230, and a protective layer 250 sequentially stacked on another surface of the polarizer 210. Although not shown in FIG. 4, the polarizing plate may further include a functional coating layer as described above on the other surface of the protective layer. Although not shown in FIG. 4, the polarizing plate may further include a resin layer, an optical film, or a stack thereof as described above on one or both surfaces of the polarizer 210.

Although not shown in FIG. 2 to FIG. 4, in an embodiment, the polarizing plate may further include an adhesive layer or a bonding layer to facilitate stacking of the polarizer, the first negative wavelength dispersion retardation layer, the positive C retardation layer, the protective layer, and the second negative wavelength dispersion retardation layer.

In an embodiment, the polarizing plate may have a light transmittance of 3% or less, for example, 0% to 3%, at a wavelength of 380 nm. Within this range, the polarizing plate can prevent or substantially prevent a light emitting device of a display unit described below from being damaged by UV light coming from the outside. A method of realizing light transmittance in the range described above is well known to those skilled in the art. For example, incorporating a light absorber capable of absorbing light at a wavelength 380 nm into one of the components of the polarizing plate may be considered.

### Stereoscopic Image Display Apparatus

In accordance with another aspect of the present invention, a stereoscopic image display apparatus includes: a display unit having a light emitting device; a first polarizing plate, and a pancake lens assembly, wherein the first polarizing plate includes the polarizing plate described above.

### The First Polarizing Plate

The first polarizing plate may be substantially the same as the polarizing plate described above. Accordingly, a further detailed description of the first polarizing plate will be omitted.

The first polarizing plate may be disposed between the display unit and the pancake lens assembly.

The first polarizing plate may include a negative wavelength dispersion retardation layer disposed at a side thereof facing the display unit and a negative wavelength dispersion retardation layer disposed at a side thereof facing the pancake lens assembly.

According to an implementation, the negative wavelength dispersion retardation layer disposed at the side of the first polarizing plate facing the display unit may be the first negative wavelength dispersion retardation layer described above, and the negative wavelength dispersion retardation layer disposed at the side of the first polarizing plate facing the pancake lens assembly may be the second negative wavelength dispersion retardation layer described above.

According to another implementation, the negative wavelength dispersion retardation layer disposed at the side of the first polarizing plate facing the display unit may be the second negative wavelength dispersion retardation layer described above, and the negative wavelength dispersion retardation layer disposed at the side of the first polarizing plate facing the pancake lens assembly may be the first negative wavelength dispersion retardation layer described above.

According to a further embodiment, the negative wavelength dispersion retardation layer disposed at the side of the first polarizing plate facing the display unit may be the first negative wavelength dispersion retardation layer described above, and the negative wavelength dispersion retardation layer disposed at the side of the first polarizing plate facing the pancake lens assembly may be the first negative wavelength dispersion retardation layer described above.

In an embodiment, a slow axis of the negative wavelength dispersion retardation layer disposed at the side of the first polarizing plate facing the pancake lens assembly is substantially orthogonal to a slow axis of a retardation film of the pancake lens assembly described below. Herein, “substantially orthogonal” refers to an angle in a range of 90°±5°, and, in an embodiment, an angle of 90°. With this structure, the first polarizing plate can eliminate or reduce ghost images while preventing or substantially preventing light leakage due to internal scattering.

A slow axis of the negative wavelength dispersion retardation layer disposed at the side of the first polarizing plate facing the display unit may be substantially orthogonal to the slow axis of the negative wavelength dispersion retardation layer disposed at the side of the first polarizing plate facing the pancake lens assembly. Herein, “substantially orthogonal” refers to an angle in a range of 90°±5°, and, in an embodiment, an angle of 90°. This structure can aid in reducing light loss and producing the same level of light output for each wavelength by providing that the degree of circular polarization that light from the display unit undergoes while passing through the negative wavelength dispersion retardation layer disposed at the side of the first polarizing plate facing the display unit is substantially the same as the degree of circular polarization that the light undergoes while sequentially passing through the polarizer and the negative wavelength dispersion retardation layer disposed at the side of the first polarizing plate facing the pancake lens assembly.

If the display unit has a long side in a longitudinal direction and a short side in a transverse direction, a light absorption axis of a first polarizer may be oriented in substantially the same direction as the transverse direction of the display unit. The light absorption axis of the first polarizer corresponds to the machine direction of the first polarizer.

FIG. 6 illustrates an axial relationship between the first polarizing plate and the retardation film of the pancake lens assembly, according to an embodiment.

Referring to FIG. 6, in the first polarizing plate, the light absorption axis 211 of the first polarizer 210 may be tilted at an angle of approximately 45° with respect to the slow axis 221 of the negative wavelength dispersion retardation layer 220 at the side of the first polarizing plate facing the display unit, and the slow axis 221 of the negative wavelength dispersion retardation layer 220 at the side of the first polarizing plate facing the display unit may be substantially parallel to the slow axis 321 of the retardation film 320 of the pancake lens assembly.

### Pancake Lens Assembly

The pancake lens assembly can produce a stereoscopic image by changing an optical path of light emitted from the display unit including the light emitting device, entering the first polarizing plate, and having exited the first polarizing plate.

The pancake lens assembly may include a first lens, a retardation film, and a reflective polarizer disposed sequentially with respect to the first polarizing plate.

The first lens can enable display of a stereoscopic image while providing enhanced luminous efficacy by transmitting light coming in from the first polarizing plate to the retardation film therethrough or by reflecting circularly polarized light from the retardation film.

One of two surfaces of the first lens may be curved to facilitate achievement of the functions described above. For example, the first lens may be a spherical concave lens, a spherical convex lens, a planar lens, a rotationally symmetrical aspherical lens, or a free-form lens.

The first lens may be formed of glass or plastic, and may be manufactured by a method known in the art with regard to typical pancake lenses.

The retardation film has a slow axis in an in-plane direction thereof, wherein the slow axis of the retardation film may be orthogonal or approximately orthogonal to the slow axis of the negative wavelength dispersion retardation layer disposed at the side of the first polarizing plate facing the pancake lens assembly. If the slow axis of the retardation film is not substantially orthogonal to the slow axis of the negative wavelength dispersion retardation layer disposed at the side of the first polarizing plate facing the pancake lens assembly, the pancake lens assembly can fail to produce an enlarged image through an optical system thereof since light entering the pancake lens assembly cannot be returned to an original polarization state thereof, despite being magnified along a normal optical path in the pancake lens assembly.

Referring to FIG. 6, the slow axis 241 of the negative wavelength dispersion retardation layer 240 at the side of the first polarizing plate facing the pancake lens assembly may be substantially orthogonal to the slow axis 321 of the retardation film 320 of the pancake lens assembly.

In an embodiment, the retardation film may have an in-plane retardation of 130 nm to 150 nm, for example, 135 nm to 145 nm, at a wavelength of 550 nm. Within this range, the retardation film can produce circularly polarized light.

The retardation film may be formed of a liquid crystal layer or a non-liquid crystal layer as described above. In an embodiment, the liquid crystal layer and the non-liquid crystal layer are substantially the same as those described above, and a further detailed description thereof will be omitted.

The reflective polarizer can reflect some portion of circularly polarized light from the retardation film back to the retardation film while transmitting the other portion of the circularly polarized light therethrough.

In an embodiment, the reflective polarizer may have a structure in which two different layers having different indices of refraction are alternately stacked one above another. For example, the reflective polarizer may be a film in which two different layers having different indices of refraction are stacked in the sequence of higher refractive index layer/lower refractive index layer or lower refractive index layer/higher refractive index layer.

### Display Unit

The display unit may include a typical display unit that includes a light emitting device. The light emitting device may include at least one of an organic light emitting device, an inorganic light emitting device, or an organic/inorganic hybrid light emitting device.

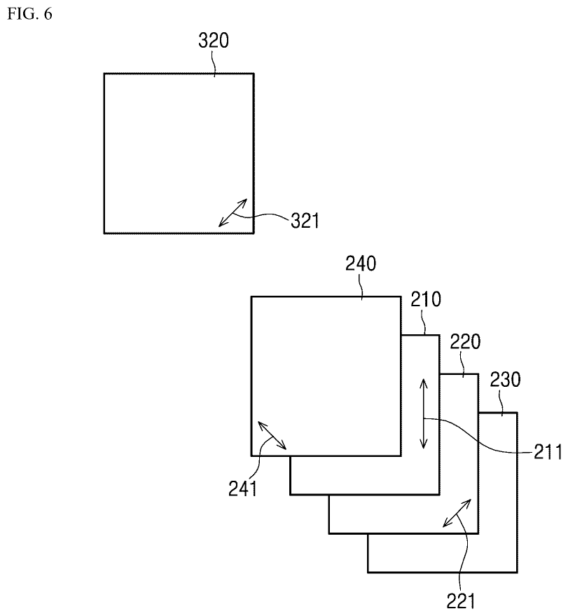

FIG. 5 is a schematic diagram of a stereoscopic image display apparatus according to an embodiment.

Referring to FIG. 5, the stereoscopic image display apparatus includes: a display unit 100; a first polarizing plate 200 including a positive C retardation layer 230, a first negative wavelength dispersion retardation layer 220, a first polarizer 210, and a second negative wavelength dispersion retardation layer 240; and a pancake lens assembly 300 including a first lens 310, a retardation film 320, and a reflective polarizer 330. Light exiting the stereoscopic image display apparatus through the pancake lens assembly 300 may be perceived by a user's eyes 1.

Referring to FIG. 5, circularly polarized light from the second negative wavelength dispersion retardation layer 240 passes through the first lens 310 and the retardation film 320, is reflected from the reflective polarizer 330 back to the retardation film 320 to be circularly polarized through the retardation film 320, is reflected from the first lens 310 back to the retardation film 320 to pass through the retardation film 320, and is linearly polarized through the reflective polarizer 330 before exiting the pancake lens assembly 300.

In an embodiment, the pancake lens assembly may further include a third polarizer disposed at a side of the reflective polarizer facing away from the retardation film, that is, at an outermost side of the stereoscopic image display apparatus.

The third polarizer can aid in minimizing or reducing ghost images by absorbing linearly polarized light traveling in a different direction than linearly polarized light from the reflective polarizer (that is, linearly polarized light substantially orthogonal to linearly polarized light from the reflective polarizer).

The third polarizer may have a light absorption axis in an in-plane direction thereof, wherein the light absorption axis may be substantially orthogonal to a light absorption axis of the first polarizer of the first polarizing plate. Herein, “substantially orthogonal” may include an angle of 90° or an angle in the range of 90°±5°.

In an embodiment, the light absorption axis of the third polarizer may be substantially identical to the machine direction of the third polarizer.

In an embodiment, the third polarizer may be manufactured by a method the same or substantially the same as the method described above with regard to the first polarizer.

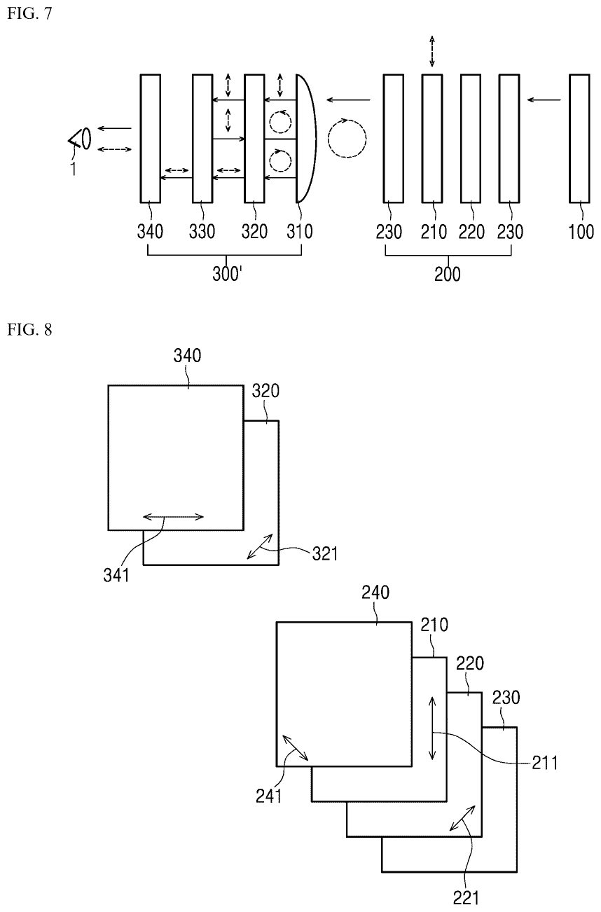

FIG. 7 is a schematic diagram of a stereoscopic image display apparatus according to another embodiment.

Referring to FIG. 7, the stereoscopic image display apparatus according to the present embodiment may include a pancake lens assembly 300′ including a first lens 310, a retardation film 320, a reflective polarizer 330, and a third polarizer 340, instead of the pancake lens assembly 300 of FIG. 5. The third polarizer 340 can minimize or reduce ghost images by transmitting a portion of linearly polarized light from the reflective polarizer 330 therethrough while absorbing linearly polarized light substantially orthogonal thereto.

FIG. 8 illustrates an axial relationship between the first polarizing plate, the retardation film of the pancake lens assembly, and the third polarizer of the pancake lens assembly, according to an embodiment.

Referring to FIG. 8, in the first polarizing plate, a light absorption axis 211 of the first polarizer 210 may be tilted at an angle of approximately 45° with respect to a slow axis 221 of the first negative wavelength dispersion retardation layer 220 disposed at a side of the first polarizing plate facing the display unit; the slow axis 221 of the first negative wavelength dispersion retardation layer 220 disposed at the side of the first polarizing plate facing the display unit is parallel or substantially parallel to a slow axis 321 of the retardation film 320 of the pancake lens assembly 300; and the light absorption axis 211 of the first polarizer 210 may be orthogonal or substantially orthogonal to a light absorption axis 341 of the third polarizer 340.

A stereoscopic image display apparatus according to another embodiment will now be described.

The stereoscopic image display apparatus may further include a second polarizing plate between the first polarizing plate and the pancake lens assembly.

The second polarizing plate can enhance luminous efficacy by transmitting circularly polarized light from the first polarizing plate therethrough or by causing non-circularly polarized light from the first polarizing plate to be circularly polarized before exiting the second polarizing plate.

The second polarizing plate may include: a second polarizer; a first retardation layer bonded to a surface of the second polarizer facing the display unit; and a second retardation layer bonded to a surface of the second polarizer facing the pancake lens assembly.

According to an embodiment, each of the first retardation layer and the second retardation layer may have negative wavelength dispersion.

In an embodiment, each of the first retardation layer and the second retardation layer has a short wavelength dispersion of 0.81 to 0.88 and a long wavelength dispersion of 1.01 to 1.04. Within these ranges, the first retardation layer and the second retardation layer can enhance luminance of the stereoscopic image display apparatus through an increase in internal transmittance.

In an embodiment, the first retardation layer may have an in-plane retardation of 115 nm to 125 nm, for example, 119 nm to 123 nm, at a wavelength of 450 nm. In an embodiment, the first retardation layer may have an in-plane retardation of 135 nm to 145 nm, for example, 139 nm to 143 nm, at a wavelength of 550 nm. In an embodiment, the first retardation layer may have an in-plane retardation of 140 nm to 150 nm, for example, 142 nm to 146 nm, at a wavelength of 650 nm. Within these ranges, the first retardation layer can have a short wavelength dispersion and a long wavelength dispersion within the ranges described above.

In an embodiment, the second retardation layer may have an in-plane retardation of 115 nm to 125 nm, for example, 119 nm to 123 nm, at a wavelength of 450 nm. In an embodiment, the second retardation layer may have an in-plane retardation of 135 nm to 145 nm, for example, 139 nm to 143 nm, at a wavelength of 550 nm. In an embodiment, the second retardation layer may have an in-plane retardation of 140 nm to 150 nm, for example, 142 nm to 146 nm, at a wavelength of 650 nm. Within these ranges, the second retardation layer can have a short wavelength dispersion and a long wavelength dispersion within the ranges described above.

In an embodiment, the short wavelength dispersion of the first retardation layer may be substantially equal to that of the second retardation layer, and the long wavelength dispersion of the first retardation layer may be substantially equal to that of the second retardation layer. Accordingly, it is possible to prevent failure to provide uniform images due to different degrees of circular polarization for different wavelengths that cause a user to perceive different levels of light output for different wavelengths. Herein, “substantially equal” includes an error span of −0.001 to +0.001, in addition to being completely equal.

Each of the first retardation layer and the second retardation layer has a slow axis in an in-plane direction thereof, wherein the slow axis of the first retardation layer is substantially orthogonal to the slow axis of the second retardation layer.

The slow axis of the first retardation layer may be tilted at an angle of approximately 45° with respect to a reference. The slow axis of the second retardation layer may be tilted at an angle of approximately 135° with respect to the reference. Within these ranges, each of the first retardation layer and the second retardation layer can enhance the degree of circular polarization of light from the display unit for each wavelength. Herein, the “reference” refers to the light absorption axis of the first polarizer of the first polarizing plate. The light absorption axis of the first polarizer corresponds to the machine direction of the first polarizer. Assuming that the display unit has a long side in a longitudinal direction and a short side in a transverse direction, the light absorption axis of the first polarizer may be oriented in substantially the same direction as the transverse direction of the display unit.

In an embodiment, the first retardation layer may have an out-of-plane retardation of 50 nm to 80 nm, for example, 55 nm to 75 nm, at a wavelength of 550 nm. Within this range, the first retardation layer can have an in-plane retardation within the range described above while allowing reduction in thickness of the second polarizing plate.

In an embodiment, the first retardation layer may have a degree of biaxiality of 0.7 to 1.1, for example, 0.8 to 1.0, at a wavelength of 550 nm. Within this range, the first retardation layer can have an in-plane retardation within the range described above while allowing reduction in thickness of the first polarizing plate.

In an embodiment, the second retardation layer may have an out-of-plane retardation of 50 nm to 80 nm, for example, 55 nm to 75 nm, at a wavelength of 550 nm. Within this range, the second retardation layer can have an in-plane retardation within the range described above while allowing reduction in thickness of the second polarizing plate.

In an embodiment, the second retardation layer may have a degree of biaxiality of 0.7 to 1.1, for example, 0.8 to 1.0, at a wavelength of 550 nm. Within this range, the second retardation layer can have an in-plane retardation within the range set forth above while allowing in reduction in thickness of the second polarizing plate.

In an embodiment, each of the first retardation layer and the second retardation layer may have a thickness of 1 μm to 40 μm, for example, 1.5 μm to 35 μm. Within this range, each of the first retardation layer and the second retardation layer can be used in the first polarizing plate.

Each of the first retardation layer and the second retardation layer may be formed of any suitable material that can satisfy the wavelength dispersion and retardation requirements described above. Each of the first retardation layer and the second retardation layer may be a liquid crystal layer or a non-liquid crystal layer.

In an embodiment, the liquid crystal layer and the non-liquid crystal layer may be the same as those described above with regard to the first polarizing plate, and further description thereof will be omitted. It is to be understood that each of the first retardation layer and the second retardation layer may also further include an optical film as described above.

In an embodiment, each of the first retardation layer and the second retardation layer may further include an optical film. The optical film may facilitate formation of a coating layer as described above without affecting retardation characteristics of the first retardation layer and the second retardation layer. The optical film may be substantially the same as that described above, and further description thereof will be omitted.

The second polarizer may linearly polarize circularly polarized light from the first retardation layer to direct the linearly polarized light to the second retardation layer.

The second polarizer may have a light absorption axis in an in-plane direction thereof, wherein the light absorption axis may be substantially parallel to the light absorption axis of the first polarizer of the first polarizing plate. Herein, “substantially parallel” means an angle of 0° or an angle in the range of 0°±5°.

In an embodiment, the second polarizer may have a crossed transmittance of 0.2% or less, for example, 0.01% or less, for example, 0% to 0.2% or 0% to 0.01%. Within this range, the second polarizer can aid in minimizing or reducing ghost images by enhancing antireflection performance of the display apparatus in which an angular relationship between the slow axes is set as described above.

In an embodiment, the second polarizer may have a degree of polarization of 99% or more, for example, 99.99% to 100%, and a single light transmittance (Ts) of 42% or more, for example, 42% to 45%. Within these ranges of degree of polarization and single light transmittance, the second polarizer can have significantly low reflectance when stacked on the retardation layer stack.

The light absorption axis of the second polarizer may be a stretching direction of a polyvinyl alcohol film in manufacture of the second polarizer therefrom, for example, the machine direction (MD) of the second polarizer. The second polarizer may include a polyvinyl alcohol-based polarizer obtained by uniaxially stretching a polyvinyl alcohol film. In an embodiment, the second polarizer may be manufactured by subjecting the polyvinyl alcohol film to dyeing, stretching, crosslinking, and color correction processes. A polarizer having a degree of polarization and light transmittance within the ranges set forth above may be obtained by appropriately varying conditions of the dyeing, stretching, crosslinking, and color correction processes described above.

In an embodiment, the second polarizer may have a thickness of 5 μm to 40 μm. Within this range, the second polarizer can be used in the second polarizing plate.

The second polarizing plate may further include a resin layer formed on a surface of the second polarizer facing the pancake lens assembly.

In an embodiment, the resin layer may be directly formed on and bonded to the surface of the second polarizer facing the pancake lens assembly. Herein, the expression “directly formed” means that no other adhesive layer, bonding layer, and/or curable coating layer is formed between the second polarizer and the resin layer. The resin layer can improve the effectiveness of the second polarizing plate in elimination or reduction of ghost images by covering fine surface irregularities of the second polarizer. The resin layer may be a cured product of a composition including at least one of a heat-curable resin or a UV-curable resin. Each of the heat-curable resin and the UV-curable resin may be selected from among typical heat-curable resins or UV-curable resins known to those skilled in the art. For example, the resin layer may be a cured product of a composition including a (meth)acrylic resin.

In another embodiment, a stack of the resin layer and an optical film may be formed on the surface of the second polarizer facing the pancake lens assembly. The optical film can increase mechanical strength of the second polarizer, and the resin layer can improve the effectiveness of the second polarizing plate in elimination or reduction of ghost images by covering fine surface irregularities of the optical film. The resin layer and the optical film may be substantially the same as those described above.

In an embodiment, the resin layer may be a hard coating layer, without being limited thereto.

The second polarizing plate may further include a protective layer, a functional coating layer, or a protective layer with a functional coating layer formed thereon at an outermost side thereof facing the pancake lens assembly. In an embodiment, the protective layer, the functional coating layer, or the protective layer with the functional coating layer formed thereon are substantially the same as those described above, and further detailed description thereof will be omitted.

The second polarizing plate may further include a positive C layer. In an embodiment, the positive C layer is substantially the same as the positive C layer described above, and further detailed description thereof will be omitted.

FIG. 9 is a cross-sectional view of a second polarizing plate according to an embodiment.

Referring to FIG. 9, the second polarizing plate may include: a second polarizer 410; a first retardation layer 420 and a positive C retardation layer 430 sequentially bonded to a surface of the second polarizer 410 facing a display unit (not shown); and a second retardation layer 440 and a protective layer 450 sequentially bonded to a surface of the second polarizer 410 facing a pancake lens assembly (not shown), wherein the protective layer 450 has a functional coating layer formed thereon.

Although not shown in FIG. 9, a bonding layer or an adhesive layer (for example, a pressure sensitive adhesive (PSA) layer) may be disposed to bond the first retardation layer, the second retardation layer, and the protective layer to the second polarizer.

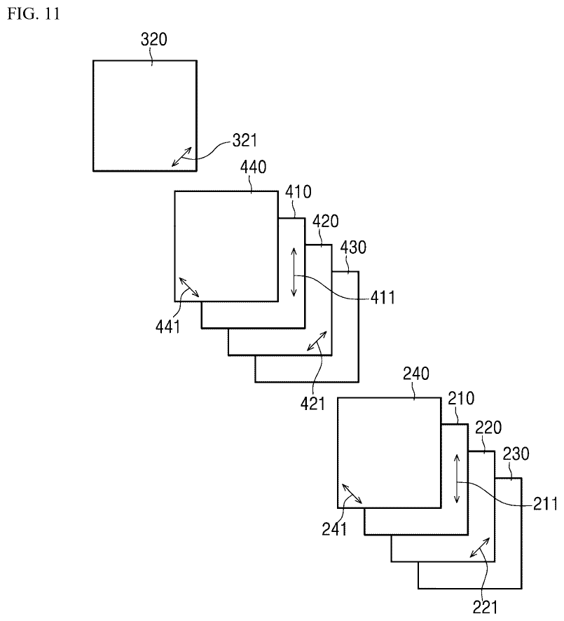

FIG. 11 illustrates an axial relationship between the first polarizing plate, the retardation film of the pancake lens assembly, and the second polarizing plate, according to another embodiment.

Referring to FIG. 11, in the second polarizing plate, a light absorption axis 411 of the second polarizer 410 may be tilted at an angle of approximately 45° with respect to a slow axis 421 of the first retardation layer 420, and the slow axis 421 of the first retardation layer 420 may be orthogonal or substantially orthogonal to a slow axis 441 of the second retardation layer 440.

In an embodiment, the second polarizing plate may have a light transmittance of 3% or less, for example, 0% to 3%, at a wavelength of 380 nm. Within this range, the second polarizing plate can prevent or substantially prevent damage to the light emitting device of the display unit due to UV light coming in from the outside. A method of realizing light transmittance in the range described above is well known to those skilled in the art. For example, incorporating a light absorber capable of absorbing light at a wavelength of 380 nm into one of the components of the first polarizing plate may be considered.

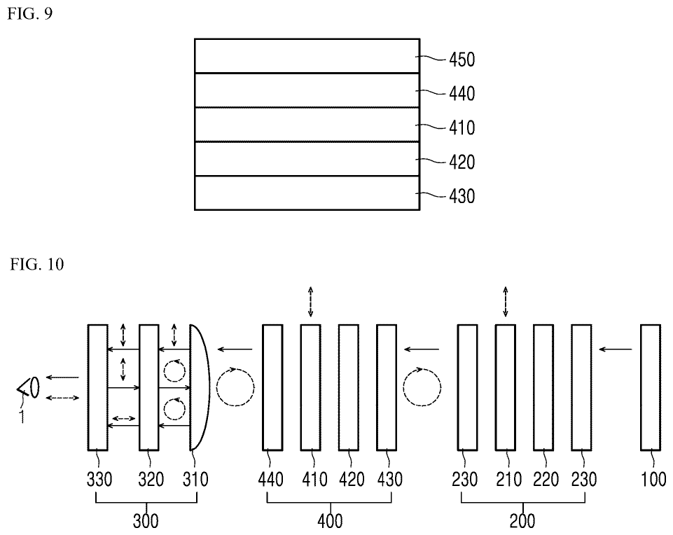

FIG. 10 is a schematic diagram of a stereoscopic image display apparatus according to another embodiment.

Referring to FIG. 10, the stereoscopic image display apparatus according to the present embodiment may further include a second polarizing plate 400 disposed between a pancake lens assembly 300 and a first polarizing plate 200, wherein the second polarizing plate 400 includes a second polarizer 410, a first retardation layer 420, a positive C layer 430, and a second retardation layer 440, as compared with the stereoscopic image display apparatus of FIG. 5.

Although not shown in FIG. 10, the stereoscopic image display apparatus may further include a second lens disposed between the second polarizing plate 400 and the first polarizing plate 200.

The second lens can produce an enlarged image by magnifying circularly polarized light from the first polarizing plate.

One of two surfaces of the second lens may be curved to facilitate achievement of the functions described above. For example, the second lens may be a spherical concave lens, a spherical convex lens, a planar lens, a rotationally symmetrical aspherical lens, or a free-form lens.

The second lens may be formed of glass or plastic. The second lens may be manufactured by a method known in the art with regard to typical pancake lenses.

Next, the present invention will be described in further detail with reference to some examples. However, these examples are provided for illustration and are not to be construed in any way as limiting the present invention.

### EXAMPLE 1

A first polarizer (single light transmittance: 44%, crossed transmittance: 0.2%, thickness: 10 μm) was manufactured by dyeing a polyvinyl alcohol film (thickness: 60 μm, Kuraray Co., Ltd.) in an aqueous solution of iodine at 55° C., followed by uniaxially stretching the dyed film to six times an initial length thereof in the MD.

After a triacetylcellulose film was attached to one surface of the first polarizer, a composition including an acrylic resin was coated onto one surface of the triacetylcellulose film, followed by curing, thereby manufacturing a stack in which the triacetylcellulose film and a resin layer were sequentially formed on the one surface of the first polarizer.

A stack of a positive C retardation layer and a first negative wavelength dispersion retardation layer was attached to one surface of the manufactured stack. The degrees of biaxiality of the stack of the positive C retardation layer and the first negative wavelength dispersion retardation layer at wavelengths of 450 nm, 550 nm, and 650 nm are shown in Table 1.

A second negative wavelength dispersion retardation layer was attached to another surface of the manufactured stack, thereby manufacturing a first polarizing plate in which the positive C retardation layer (liquid crystal layer), the first negative wavelength dispersion retardation layer (liquid crystal layer), the first polarizer, the triacetylcellulose film, the resin layer, and the second negative wavelength dispersion retardation layer (liquid crystal layer) were sequentially stacked one above another. Each of the first negative wavelength dispersion retardation layer and the second negative wavelength dispersion retardation layer had negative wavelength dispersion. The short wavelength dispersion and the long wavelength dispersion of each of the first negative wavelength dispersion retardation layer and the second negative wavelength dispersion retardation layer are shown in Table 1.

The manufactured first polarizing plate, a display unit including an OLED device, and a pancake lens assembly were combined as shown in FIG. 5, thereby manufacturing a module for a stereoscopic image display apparatus.

Here, a slow axis of the second negative wavelength dispersion retardation layer of the first polarizing plate was orthogonal to a slow axis of a retardation film of the pancake lens assembly.

In the first polarizing plate, a light absorption axis of the first polarizer was tilted at an angle of 45° with respect to a slow axis of the first negative wavelength dispersion retardation layer, and the slow axis of the first negative wavelength dispersion retardation layer was orthogonal to a slow axis of the second negative wavelength dispersion retardation layer.

### EXAMPLES 2 TO 5

Modules for stereoscopic image display apparatuses were manufactured in the same manner as in Example 1 except that the degree of biaxiality of the stack of the positive C retardation layer and the first negative wavelength dispersion retardation layer was changed as listed in Table 1.

### EXAMPLE 6

A second polarizer (light transmittance: 44%, crossed transmittance: 0.2%, thickness: 10 μm) was manufactured by dyeing a polyvinyl alcohol film (thickness: 60 μm, Kuraray Co., Ltd.) in an aqueous solution of iodine at 55° C., followed by uniaxially stretching the dyed film to six times an initial length thereof in the MD.

After a triacetylcellulose film was attached to one surface of the second polarizer, a composition including an acrylic resin was coated onto one surface of the triacetylcellulose film, followed by curing, thereby manufacturing a stack of the second polarizer, the triacetylcellulose film, and a resin layer.

A stack of a positive C retardation layer and a first retardation layer was attached to one surface of the manufactured stack.

A second retardation layer was attached to another surface of the manufactured stack, thereby manufacturing a second polarizing plate in which the positive C retardation layer (liquid crystal layer), the first retardation layer (liquid crystal layer), the second polarizer, the triacetylcellulose film, the resin layer, and the second retardation layer (liquid crystal layer) were sequentially stacked one above another. Each of the first retardation layer and the second retardation layer had negative wavelength dispersion. The short wavelength dispersion and the long wavelength dispersion of each of the first retardation layer and the second retardation layer are shown in Table 1.

A module for a stereoscopic image display apparatus was manufactured in the same manner as in Example 1 except that the manufactured second polarizing plate was further disposed between the first polarizing plate and the pancake lens assembly such that the module had a structure as shown in FIG. 10.

### EXAMPLE 7

A module for a stereoscopic image display apparatus was manufactured in the same manner as in Example 6 except that the short wavelength dispersion and the long wavelength dispersion of each of the first retardation layer and the second retardation layer of the second polarizing plate were changed as listed in Table 1.

### COMPARATIVE EXAMPLES 1 TO 6

Modules for stereoscopic image display apparatuses were manufactured in the same manner as in Example 1 except that the degree of biaxiality of the stack of the positive C retardation layer and the first negative wavelength dispersion retardation layer was changed as listed in Table 2.

*Resolution (modulation transfer function (MTF)) (unit: %): Resolution was evaluated by measuring a contrast ratio, that is, a difference in brightness between light and dark areas on a screen, using an imaging photometer (ProMetric, Radiant Imaging Co.).

$$MTF = \{ ( Maximum contrast ratio - Minimum contrast ratio ) \text{} / ( Maximum contrast ratio + Minimum contrast ratio ) \} \times 100$$

*Light leakage: Diagonal light leakage was observed with the naked eye in a darkroom. When no light leakage was observed with the naked eye, a corresponding module was rated as “undetectable” and, when light leakage was observed with the naked eye, a corresponding module was rated as “weak”, “medium”, or “strong” based on the observed intensity of light leakage.

*Color Uniformity: Using an imaging photometer (ProMetric, Radiant Imaging Co.), front colors of a screen (u′1, v′1 (CIE 1976 UCS color coordinate system)) were measured and lateral colors of the screen (u′2, v′2) at an azimuth of 45° and an incident angle of 60° were measured. From the measured u′ and v′ values, Au′v′ was calculated according to the following equation. A higher value of Au′v′ indicates a narrower field of view due to lower color uniformity of the screen when viewed from the front and side.

$$Δ {u}^{′} {v}^{′} = \sqrt{{( {u}_{2}^{′} - {u}_{1}^{′} )}^{2} + {( {v}_{2}^{′} - {v}_{1}^{′} )}^{2}}$$

TABLE 1

| | | | Example | | | | | | |
|---|---|---|---|---|---|---|---|---|---|
| | | | 1 | 2 | 3 | 4 | 5 | 6 | 7 |
| Stack | NZ | @450 nm | 0.291 | 0.382 | 0.130 | 0.257 | 0.314 | 0.291 | 0.382 |
| | | @550 nm | 0.407 | 0.477 | 0.291 | 0.407 | 0.407 | 0.407 | 0.477 |
| | | @650 nm | 0.401 | 0.484 | 0.319 | 0.441 | 0.401 | 0.401 | 0.484 |
| First | | Short | 0.85 | 0.85 | 0.85 | 0.81 | 0.88 | 0.85 | 0.85 |
| negative | | wavelength | | | | | | | |
| wavelength | | dispersion | | | | | | | |
| dispersion | | Long | 1.02 | 1.05 | 1.07 | 1.10 | 1.02 | 1.02 | 1.05 |
| retardation | | wavelength | | | | | | | |
| layer | | dispersion | | | | | | | |
| | | Re | 142 | 142 | 140 | 142 | 142 | 142 | 142 |
| | | Rth | 66.7 | 66.7 | 65.8 | 66.7 | 66.7 | 66.7 | 66.7 |
| Positive | Rₜₕ | @450 nm | −82 | −71 | −100 | −82 | −82 | −82 | −71 |
| C layer | | @550 nm | −80 | −70 | −95 | −80 | −80 | −80 | −70 |
| | | @650 nm | −78 | −68 | −93 | −78 | −78 | −78 | −68 |

| Second | Short | 0.85 | 0.85 | 0.85 | 0.81 | 0.88 | 0.85 | 0.85 |
|---|---|---|---|---|---|---|---|---|
| negative | wavelength | | | | | | | |
| wavelength | dispersion | | | | | | | |
| dispersion | Long | 1.02 | 1.05 | 1.07 | 1.10 | 1.02 | 1.02 | 1.05 |
| retardation | wavelength | | | | | | | |
| layer | dispersion | | | | | | | |
| | Re | 142 | 142 | 140 | 142 | 142 | 142 | 142 |
| First | Short | — | — | — | — | — | 0.85 | 0.85 |
| retardation | wavelength | | | | | | | |
| layer of | dispersion | | | | | | | |
| second | Long | — | — | — | — | — | 1.02 | 1.05 |
| polarizing | wavelength | | | | | | | |
| plate | dispersion | | | | | | | |
| Second | Short | — | — | — | — | — | 0.85 | 0.85 |
| retardation | wavelength | | | | | | | |
| layer of | dispersion | | | | | | | |
| second | Long | — | — | — | — | — | 1.02 | 1.05 |
| polarizing | wavelength | | | | | | | |
| plate | dispersion | | | | | | | |

| | | | | | | | |
|---|---|---|---|---|---|---|---|
| Resolution | 95 | 92 | 90 | 90 | 91 | 96 | 95 |
| Light leakage | Unde- | Unde- | Unde- | Unde- | Unde- | Unde- | Unde- |
| | tectable | tectable | tectable | tectable | tectable | tectable | tectable |
| Color Uniformity | 0.10 | 0.10 | 0.12 | 0.11 | 0.12 | 0.10 | 0.10 |

TABLE 2

| | | | Comparative Example | | | | | |
|---|---|---|---|---|---|---|---|---|
| | | | 1 | 2 | 3 | 4 | 5 | 6 |
| Stack | NZ | @450 nm | 0.027 | 0.540 | 0.112 | 0.469 | 0.106 | 0.307 |
| | | @550 nm | 0.418 | 0.599 | 0.170 | 0.632 | 0.231 | 0.477 |
| | | @650 nm | 0.413 | 0.583 | 0.311 | 0.619 | 0.249 | 0.747 |
| First | | Short | 0.6 | 0.88 | 0.95 | 0.81 | 0.88 | 0.85 |
| negative | | wavelength | | | | | | |
| wavelength | | dispersion | | | | | | |
| dispersion | | Long | 1.02 | 1.02 | 1.1 | 1.01 | 1.05 | 1.02 |
| retardation | | wavelength | | | | | | |
| layer | | dispersion | | | | | | |
| | | Re | 145 | 145 | 130 | 148 | 142 | 142 |
| | | Rth | 68.2 | 65.8 | 61.1 | 69.6 | 69.6 | 66.7 |
| Positive | Rth | @450 nm | −82 | −53 | −106 | −60 | −108 | −80 |
| C layer | | @550 nm | −80 | −52 | −104 | −50 | −105 | −70 |
| | | @650 nm | −78 | −51 | −90 | −48 | −103 | −28 |

| Second | Short | 0.85 | 0.85 | 0.85 | 0.85 | 0.85 | 0.85 |
|---|---|---|---|---|---|---|---|
| negative | wavelength | | | | | | |
| wavelength | dispersion | | | | | | |
| dispersion | Long | 1.02 | 1.02 | 1.02 | 1.02 | 1.02 | 1.02 |
| retardation | wavelength | | | | | | |
| layer | dispersion | | | | | | |
| | Re | 142 | 142 | 142 | 142 | 142 | 142 |

| | | | | | | |
|---|---|---|---|---|---|---|
| Resolution | 62 | 61 | 40 | 62 | 45 | 61 |
| Light leakage | Medium | Medium | Strong | Medium | Strong | Medium |
| Color Uniformity | 0.22 | 0.20 | 0.22 | 0.23 | 0.32 | 0.29 |

As can be seen from Table 1, the polarizing plates of Examples 1 to 7 could produce the same level of light output for each wavelength to allow a user to perceive the same level of light output for each wavelength, could eliminate light leakage at an edge of a screen within a viewer's field of view, and could provide high resolution and a wide field of view.

By contrast, as can be seen from Table 2, the polarizing plates of Comparative Examples 1 to 6 exhibited poor properties in terms of resolution, light leakage, and color uniformity, as compared to the polarizing plates of Examples 1 to 7.

While some example embodiments have been described herein, it is to be understood that various modifications, changes, alterations, and equivalent embodiments can be made by those skilled in the art without departing from the spirit and scope of the invention.

What is claimed is:

1. A polarizing plate comprising:
a polarizer; and
a stack of a first negative wavelength dispersion retardation layer and a positive C retardation layer on at least one surface of the polarizer,
wherein the stack has a degree of biaxiality of 0.1 to 0.5 at a wavelength of 450 nm, a degree of biaxiality of 0.2 to 0.6 at a wavelength of 550 nm, and a degree of biaxiality of 0.3 to 0.7 at a wavelength of 650 nm.

2. The polarizing plate as claimed in claim 1, wherein the first negative wavelength dispersion retardation layer is between the polarizer and the positive C retardation layer.

3. The polarizing plate as claimed in claim 1, wherein the stack has an in-plane retardation of 130 nm to 150 nm and an out-of-plane retardation of −55 nm to 5 nm at a wavelength of 550 nm.

4. The polarizing plate as claimed in claim 1, wherein the first negative wavelength dispersion retardation layer has an in-plane retardation of 135 nm to 145 nm and an out-of-plane retardation of 50 nm to 70 nm at a wavelength of 550 nm.

5. The polarizing plate as claimed in claim 1, wherein the positive C retardation layer has positive wavelength dispersion.

6. The polarizing plate as claimed in claim 1, wherein the polarizer has a crossed transmittance of 0.2% or less.

7. The polarizing plate as claimed in claim 1, further comprising a resin layer on at least one surface of the polarizer.

8. The polarizing plate as claimed in claim 1, further comprising a stack of a resin layer and an optical film on at least one surface of the polarizer.

9. The polarizing plate as claimed in claim 1, further comprising a second negative wavelength dispersion retardation layer.

10. The polarizing plate as claimed in claim 9, wherein the first negative wavelength dispersion retardation layer is on a surface of the polarizer, and the second negative wavelength dispersion retardation layer is on another surface of the polarizer.

11. The polarizing plate as claimed in claim 9, wherein the second negative wavelength dispersion retardation layer has a same short wavelength dispersion and a same long wavelength dispersion as the first negative wavelength dispersion retardation layer.

12. The polarizing plate as claimed in claim 9, wherein a slow axis of the first negative wavelength dispersion retardation layer is orthogonal to a slow axis of the second negative wavelength dispersion retardation layer.

13. The polarizing plate as claimed in claim 1, further comprising a protective layer on at least one surface of the polarizer.

14. A stereoscopic image display apparatus comprising:
a display unit comprising a light emitting device;
a first polarizing plate; and
a pancake lens assembly,
wherein the first polarizing plate comprises the polarizing plate as claimed in claim 1.

15. The stereoscopic image display apparatus as claimed in claim 14, wherein the first polarizing plate is between the display unit and the pancake lens assembly.

16. The stereoscopic image display apparatus as claimed in claim 14, wherein a slow axis of a negative wavelength dispersion retardation layer at a side of the first polarizing plate facing the pancake lens assembly is orthogonal to a slow axis of a retardation film of the pancake lens assembly.

17. The stereoscopic image display apparatus as claimed in claim 15, further comprising a second polarizing plate between the first polarizing plate and the pancake lens assembly.

18. The stereoscopic image display apparatus as claimed in claim 17, wherein the second polarizing plate comprises: a second polarizer, a first retardation layer, and a positive C retardation layer sequentially bonded to a surface of the second polarizer facing the display unit; and a second retardation layer bonded to a side of the second polarizer facing the pancake lens assembly.

19. The stereoscopic image display apparatus as claimed in claim 18, wherein each of the first retardation layer and the second retardation layer has negative wavelength dispersion.

20. The stereoscopic image display apparatus as claimed in claim 14, wherein the pancake lens assembly comprises a third polarizer.
